(19) United States
(12) Patent Application Publication
(10) Pub. No.: US 2019/0181616 A1
(43) Pub. Date: Jun. 13, 2019

(54) OPTICAL DEVICE AND METHOD FOR MANUFACTURING OPTICAL DEVICE

(71) Applicant: FUJITSU LIMITED, Kawasaki-shi (JP)

(72) Inventors: Teruo Kurahashi, Isehara (JP); Kenichi Kawaguchi, Ebina (JP)

(73) Assignee: FUJITSU LIMITED, Kawasaki-shi (JP)

(21) Appl. No.: 16/278,513

(22) Filed: Feb. 18, 2019

Related U.S. Application Data
(63) Continuation of application No. PCT/JP2016/074369, filed on Aug. 22, 2016.

(51) Int. Cl. H01S 5/323; H01S 5/32; H01S 5/026; H01S 5/20; H01S 5/02

(52) U.S. Cl. CPC H01S 5/323; H01S 5/3202; H01S 5/0203; H01S 5/20; H01S 5/3211; H01S 5/026

(57) ABSTRACT

An optical device includes lower cladding layer formed of an amorphous insulator on a substrate; a first cladding region, an active region, and a second cladding region formed on the lower cladding layer, one of the first cladding region and the second cladding region being formed on a monocrystal; an upper cladding layer formed of an insulator on the active region; a first electrode connected with the first cladding region; and a second electrode connected with the second cladding region.

### CROSS-REFERENCE TO RELATED APPLICATIONS

This application is a continuation application of International Application PCT/JP2016/074369 filed on Aug. 22, 2016 and designated the U.S., the entire contents of which are incorporated herein by reference.

### FIELD

The embodiments discussed herein are related to an optical device and a method for manufacturing an optical device.

### BACKGROUND

In optical communication or the like, optical devices have been used which have an optical waveguide formed on a silicon wafer and a light emitting element as a light source. Such an optical device may be fabricated by forming the optical waveguide with silicon on a silicon oxide film on a surface of a silicon substrate and by mounting the light emitting element as the light source, which is formed with a compound semiconductor, on the silicon substrate by flip-chip bonding, for example. However, in this method, it is difficult to perform strict positioning between the optical waveguide and the light emitting element, the light emitting element is fabricated by using a compound semiconductor wafer which is different from the silicon wafer, and the light emitting element is cut out for each element and mounted. Thus, a process becomes complicated, and time is requested.

Thus, a method has been disclosed in which a light emitting element is formed with a compound semiconductor directly on a silicon wafer in which an optical waveguide is formed of silicon. This is a method in which a region, in which the light emitting element is formed, of the silicon wafer in which the optical waveguide is formed is removed by etching, a thick buffer layer is formed in this region, and the light emitting element is formed with the compound semiconductor on the buffer layer.

Japanese Laid-open Patent Publication No. 2010-232372 and Japanese Laid-open Patent Publication No. 2002-299598 are examples of related art.

### SUMMARY

According to an aspect of the embodiments, an optical device includes a lower cladding layer formed of an amorphous insulator on a substrate; a first cladding region, an active region, and a second cladding region formed on the lower cladding layer, one of the first cladding region and the second cladding region being formed on a monocrystal; an upper cladding layer formed of an insulator on the active region; a first electrode connected with the first cladding region; and a second electrode connected with the second cladding region.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a top diagram of an optical device in a first embodiment;

FIGS. 2A and 2B are cross-sectional diagrams of the optical device in the first embodiment;

FIGS. 3A, 3B, and 3C are process diagrams (1) of a method for manufacturing a semiconductor apparatus in the first embodiment;

FIGS. 4A, 4B, and 4C are process diagrams (2) of the method for manufacturing the semiconductor apparatus in the first embodiment;

FIGS. 5A, 5B, and 5C are process diagrams (3) of the method for manufacturing the semiconductor apparatus in the first embodiment;

FIGS. 6A, 6B, and 6C are process diagrams (4) of the method for manufacturing the semiconductor apparatus in the first embodiment;

FIGS. 7A, 7B, and 7C are process diagrams (5) of the method for manufacturing the semiconductor apparatus in the first embodiment;

FIGS. 8A, 8B, and 8C are process diagrams (6) of the method for manufacturing the semiconductor apparatus in the first embodiment;

FIGS. 9A and 9B are cross-sectional diagrams of a modification example of the optical device in the first embodiment;

FIG. 10 is a top diagram of an optical device in a second embodiment;

FIGS. 11A and 11B are cross-sectional diagrams of the optical device in the second embodiment;

FIG. 12 is a top diagram of a modification example 1 of the optical device in the second embodiment;

FIGS. 13A and 13B are cross-sectional diagrams of the modification example 1 of the optical device in the second embodiment;

FIGS. 14A and 14B are explanatory diagrams of a modification example 2 of the optical device in the second embodiment; and

FIG. 15 is an explanatory diagram of a modification example 3 of the optical device in the second embodiment.

### DESCRIPTION OF EMBODIMENTS

For example, in a case where a buffer layer is formed on a silicon wafer or the like, lattice match does not occur between silicon and a compound semiconductor that forms a light emitting element. Thus, a proper crystalline compound semiconductor may not be formed even if the buffer layer is made thick, and desired properties may not be obtained. Thickly forming the buffer layer requests time or the like, leads to a cost increase, and requests positioning between an optical waveguide and the light emitting element in a film-thickness direction. Accordingly, manufacture is not easy.

It is desirable to provide an optical device in which an optical waveguide and an optical amplifier or a light emitting element are easily fabricated on the same silicon substrate.

Embodiments will hereinafter be described. The same members or the like will be provided with the same reference characters, and descriptions thereof will not be made. In drawings, for convenience, the vertical-to-horizontal ratios may not accurately be illustrated.

### First Embodiment

Optical Device

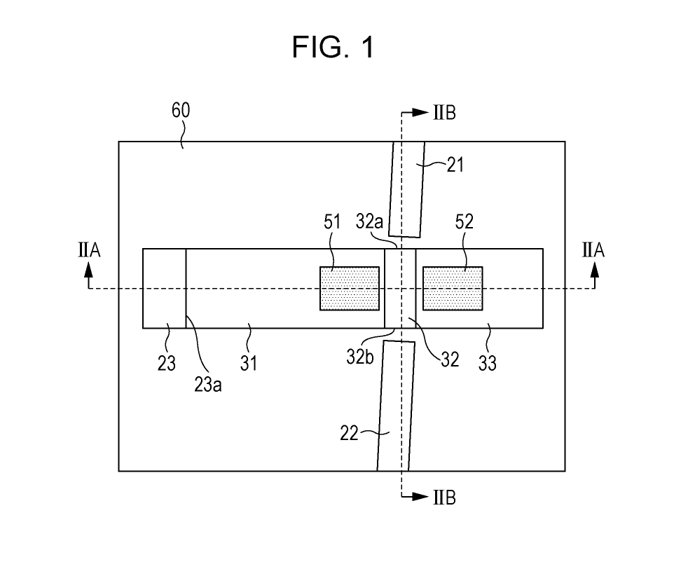

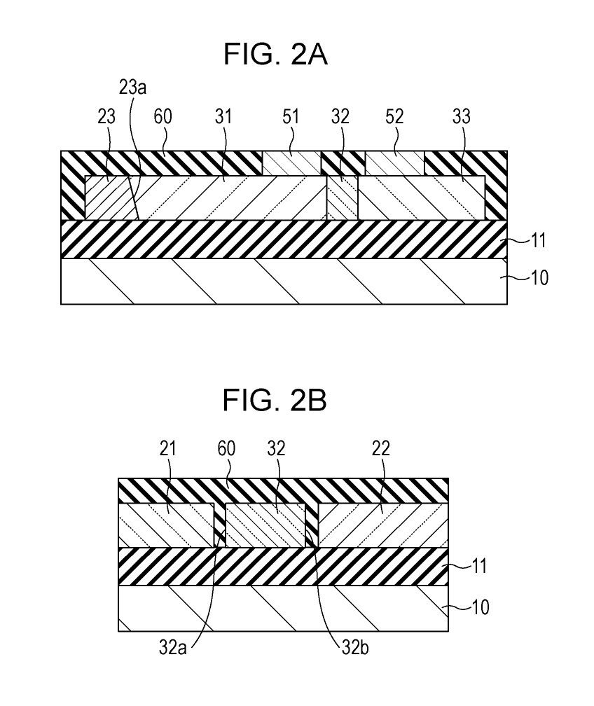

An optical device in a first embodiment will be described based on FIG. 1 and FIGS. 2A and 2B. The optical device in this embodiment has a structure in which two optical waveguides and an optical amplifier are formed and is formed on a silicon oxide layer 11 formed on a silicon substrate 10. FIG. 1 is a top diagram of the optical device in this embodiment, FIG. 2A is a cross-sectional diagram taken along dashed line IIA-IIA in FIG. 1, and FIG. 2B is a cross-sectional diagram taken along dashed line IIB-IIB in FIG. 1.

In the optical device in this embodiment, a first optical waveguide 21 and a second optical waveguide 22 are formed of silicon on the silicon oxide layer 11. The optical amplifier is formed with a compound semiconductor material between the first optical waveguide 21 and the second optical waveguide 22 on the silicon oxide layer 11. The optical amplifier is formed on the silicon oxide layer 11 along the plane direction of the silicon oxide layer 11, and a first semiconductor cladding region 31, an active region 32, and a second semiconductor cladding region 33 are formed in this order from one side to the other side. An end surface of the first semiconductor cladding region 31 as one side contacts with the (111) plane of silicon as an end surface 23a of a monocrystalline silicon region 23 formed of monocrystalline silicon.

On the monocrystalline silicon region 23, the first semiconductor cladding region 31, the active region 32, and the second semiconductor cladding region 33, a silicon oxide layer 60 is formed to cover those. The first semiconductor cladding region 31, the active region 32, and the second semiconductor cladding region 33 are formed in parallel with the plane of the silicon substrate 10. On the first semiconductor cladding region 31, a first electrode 51 is formed to contact with the first semiconductor cladding region 31. On the second semiconductor cladding region 33, a second electrode 52 is formed to contact with the second semiconductor cladding region 33. Herein, the silicon oxide layer 11 may be referred to as lower cladding layer or lower silicon oxide layer, and the silicon oxide layer 60 may be referred to as upper cladding layer or upper silicon oxide layer.

In the optical device in this embodiment, the active region 32 in the optical amplifier is formed to be positioned between the first optical waveguide 21 and the second optical waveguide 22. The silicon oxide layer 11 and the silicon oxide layer 60 are formed of silicon oxide with an amorphous structure. The first semiconductor cladding region 31 is formed of n-InP, the active region 32 is formed of InGaAsP, and the second semiconductor cladding region 33 is formed of p-InP.

Consequently, the first semiconductor cladding region 31 and the second semiconductor cladding region 33 are doped with impurity elements and thus have conductivity. Thus, a voltage is applied between the first electrode 51 and the second electrode 52, a current may thereby be caused to flow through the active region 32 via the first semiconductor cladding region 31 and the second semiconductor cladding region 33, and light may be amplified in the active region 32.

In this embodiment, in a parallel direction with a substrate surface of the silicon substrate 10, the active region 32 is interposed between the first semiconductor cladding region 31 and the second semiconductor cladding region 33 that are formed of a semiconductor material with a lower refractive index and a wider band gap than the active region 32. In a film-thickness direction, the active region 32 is interposed between the silicon oxide layer 11 and the silicon oxide layer 60 that are formed of silicon oxide, which is an insulator with a lower refractive index and a wider band gap than the active region 32. The active region 32 is, for example, interposed between the first semiconductor cladding region 31 and the second semiconductor cladding region 33 in the parallel direction with the plane of the silicon substrate 10 and is interposed between the silicon oxide layer 11 and the silicon oxide layer 60 in the vertical direction to the plane of the silicon substrate 10. Thus, the light amplified in the active region 32 is trapped in the active region 32.

Consequently, in this embodiment, the light propagated through the first optical waveguide 21 is incident on one end surface 32a of the active region 32 of the optical amplifier, amplified in the active region 32, emitted from the other end surface 32b of the active region 32, and incident on the second optical waveguide 22. In this embodiment, a case with InP, InGaAsP, and so forth is described. However, it is possible to apply other III-V compound semiconductors such as GaAs, similarly. For example, the active region 32 may be formed of InAs.

Method for Manufacturing Optical Device

Next, a description will be made about a method for manufacturing the optical device in this embodiment. The optical device described in the following has partially different portions from the shape of the optical device illustrated in FIG. 1 and FIGS. 2A and 2B in details. However, the different portions do not influence the contents of the embodiment. A silicon-on-insulator (SOI) substrate is used in manufacture of the optical device in this embodiment.

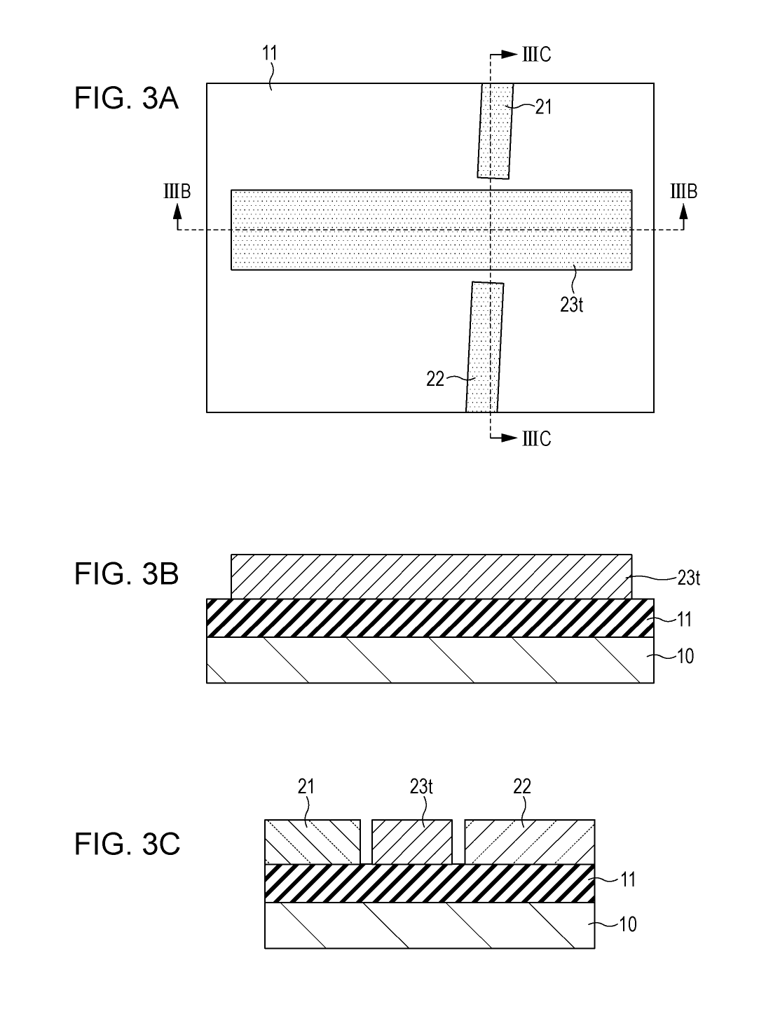

As illustrated in FIGS. 3A, 3B, and 3C, the first optical waveguide 21, the second optical waveguide 22, and a monocrystalline silicon layer 23t are first formed by processing a silicon layer in the SOI substrate. FIG. 3A is a top diagram in this process, FIG. 3B is a cross-sectional diagram taken along dashed line IIIB-IIIB in FIG. 3A, and FIG. 3C is a cross-sectional diagram taken along dashed line IIIC-IIIC in FIG. 3A.

In the SOI substrate, the silicon oxide layer 11 is formed on the silicon substrate 10, and the silicon layer is formed on the silicon oxide layer 11. The silicon layer is formed of a monocrystal whose surface is the (100) plane. In this embodiment, an SOI substrate is used in which the film thickness of the silicon oxide layer 11 is 2 to 3 μm and the film thickness of the silicon layer is 250 nm.

For example, the silicon layer of the SOI substrate is coated with a photoresist, and exposure by an exposure apparatus and development are performed. A resist pattern, which is not illustrated, is thereby formed on a region in which the first optical waveguide 21, the second optical waveguide 22, the optical amplifier, the monocrystalline silicon region 23 are formed. Subsequently, the silicon layer in a region in which the resist pattern is not formed is removed by dry etching such as reactive ion etching (RIE), and the resist pattern is thereafter removed by an organic solvent or the like. Accordingly, on the silicon oxide layer 11, the first optical waveguide 21, the second optical waveguide 22, and the monocrystalline silicon layer 23t are simultaneously formed. The monocrystalline silicon layer 23t is formed in a region in which the optical amplifier and the monocrystalline silicon region 23 are formed. The widths of the formed first optical waveguide 21 and second optical waveguide 22 are approximately 480 nm, the width of the monocrystalline silicon layer 23t in the lateral direction is approximately 1 μμm, and an interval between the first optical waveguide 21 and second optical waveguide 22 and the monocrystalline silicon layer 23t is approximately 50 nm.

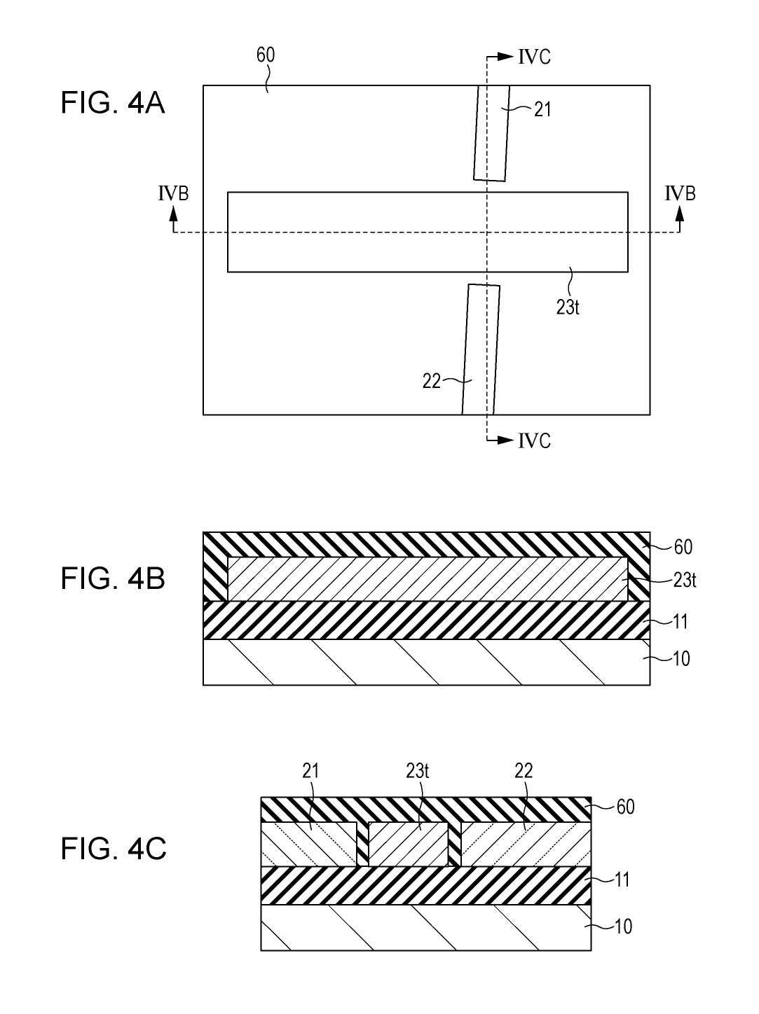

As illustrated in FIGS. 4A, 4B, and 4C, the silicon oxide layer 60 is next formed on the silicon oxide layer 11, the first optical waveguide 21, the second optical waveguide 22, and the monocrystalline silicon layer 23t, which are exposed. Accordingly, the first optical waveguide 21, the second optical waveguide 22, and the monocrystalline silicon layer 23t are covered by the silicon oxide layer 60 with the amorphous structure. For example, the silicon oxide layer 60 is formed by forming a film of silicon oxide by chemical vapor deposition (CVD). FIG. 4A is a top diagram in this process, FIG. 4B is a cross-sectional diagram taken along dashed line IVB-IVB in FIG. 4A, and FIG. 4C is a cross-sectional diagram taken along dashed line IVC-IVC in FIG. 4A.

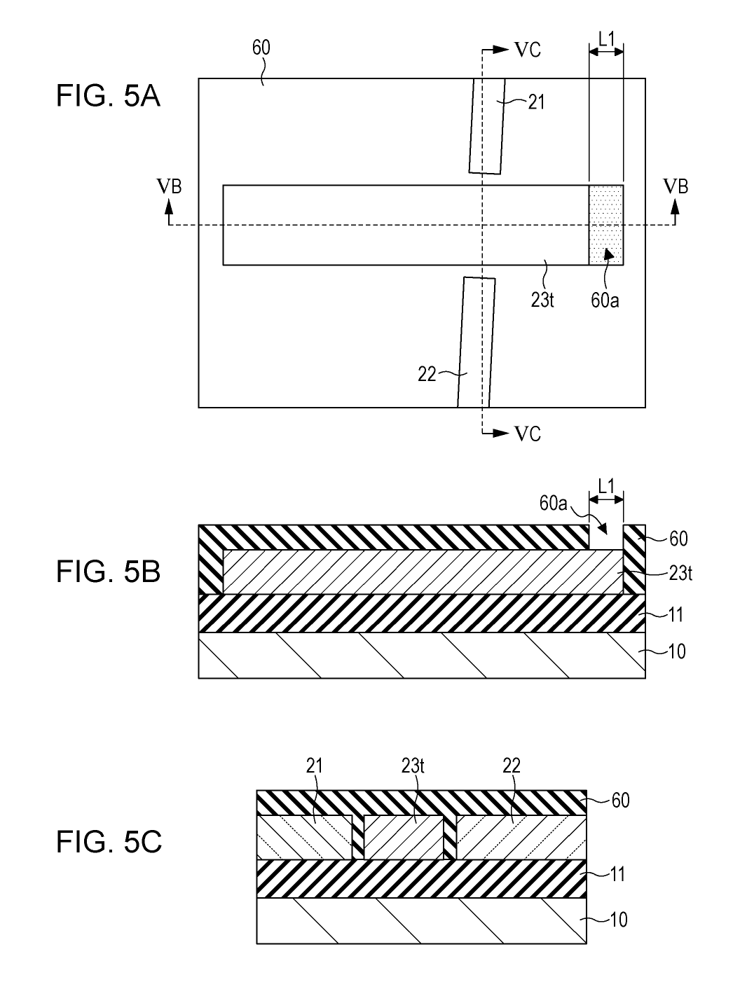

As illustrated in FIGS. 5A, 5B, and 5C, an opening 60a is next formed in the silicon oxide layer 60. The opening 60a is formed in the vicinity of an end portion of the monocrystalline silicon layer 23t in the longitudinal direction. For example, the silicon oxide layer 60 is coated with a photoresist, and exposure by an exposure apparatus and development are performed. A resist pattern that has an aperture is thereby formed in a region of the silicon oxide layer 60 in which the opening 60a is formed. Subsequently, the silicon oxide layer 60 in a region in which the resist pattern is not formed is removed by RIE or the like, a portion of a surface of the monocrystalline silicon layer 23t is exposed, and the opening 60a is thereby formed. A length L1 of the formed opening 60a is 40 to 200 μm. FIG. 5A is a top diagram in this process, FIG. 5B is a cross-sectional diagram taken along dashed line VB-VB in FIG. 5A, and FIG. 5C is a cross-sectional diagram taken along dashed line VC-VC in FIG. 5A.

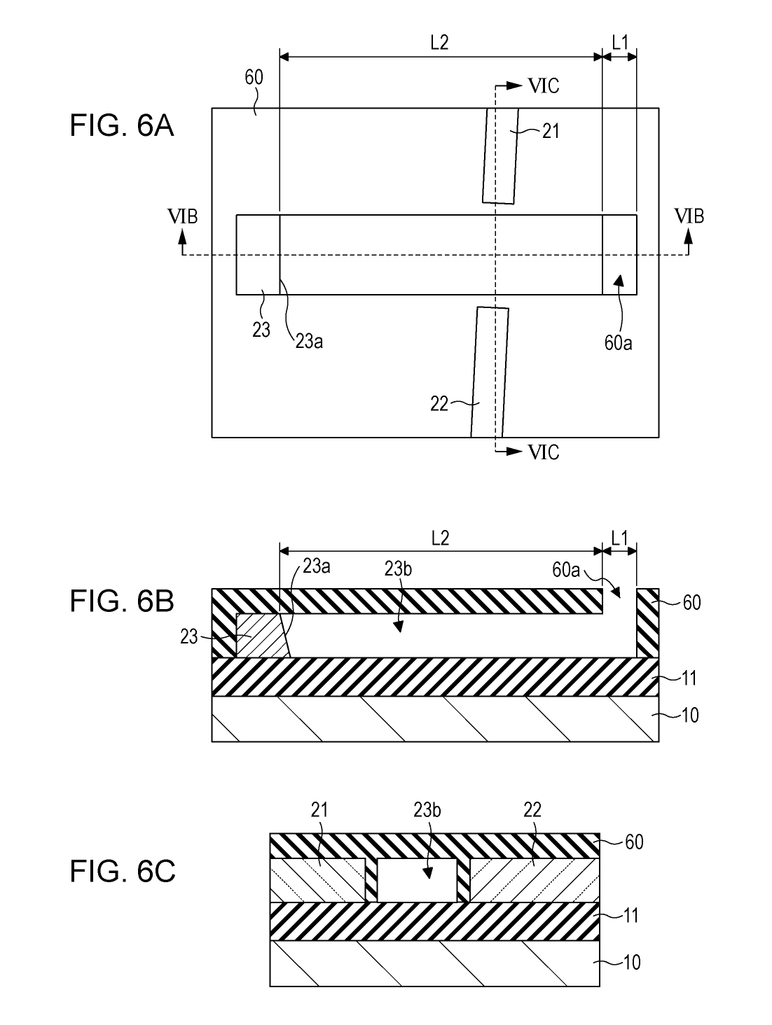

As illustrated in FIGS. 6A, 6B, and 6C, a portion of the monocrystalline silicon layer 23t is removed by wet etching by tetramethylammonium hydroxide (TMAH), and a space 23b is thereby formed. TMAH is capable of etching silicon but is not capable of etching silicon oxide. Consequently, a portion of the monocrystalline silicon layer 23t is removed by wet etching by TMAH that enters through the opening 60a of the silicon oxide layer 60. Accordingly, the space 23b is formed in a region in which the monocrystalline silicon layer 23t is removed, and the monocrystalline silicon region 23 is formed with the remaining monocrystalline silicon layer 23t. Because silicon oxide is not etched by TMAH, for example, the silicon oxide layer 60 and the silicon oxide layer 11 remain, the monocrystalline silicon layer 23t between the silicon oxide layer 60 and the silicon oxide layer 11 is removed, and the space 23b is formed in this region. Because the first optical waveguide 21 and the second optical waveguide 22 are covered by the silicon oxide layer 60, those are not removed by wet etching by TMAH. In this embodiment, a length L2 of the formed space 23b is approximately 10 μm. As described above, silicon is etched by wet etching by TMAH, and the exposed end surface 23a of the monocrystalline silicon region 23 becomes the (111) plane of silicon. In this wet etching, an etching solution may be used whose etching rate for silicon is higher than the etching rate for silicon oxide. FIG. 6A is a top diagram in this process, FIG. 6B is a cross-sectional diagram taken along dashed line VIB-VIB in FIG. 6A, and FIG. 6C is a cross-sectional diagram taken along dashed line VIC-VIC in FIG. 6A.

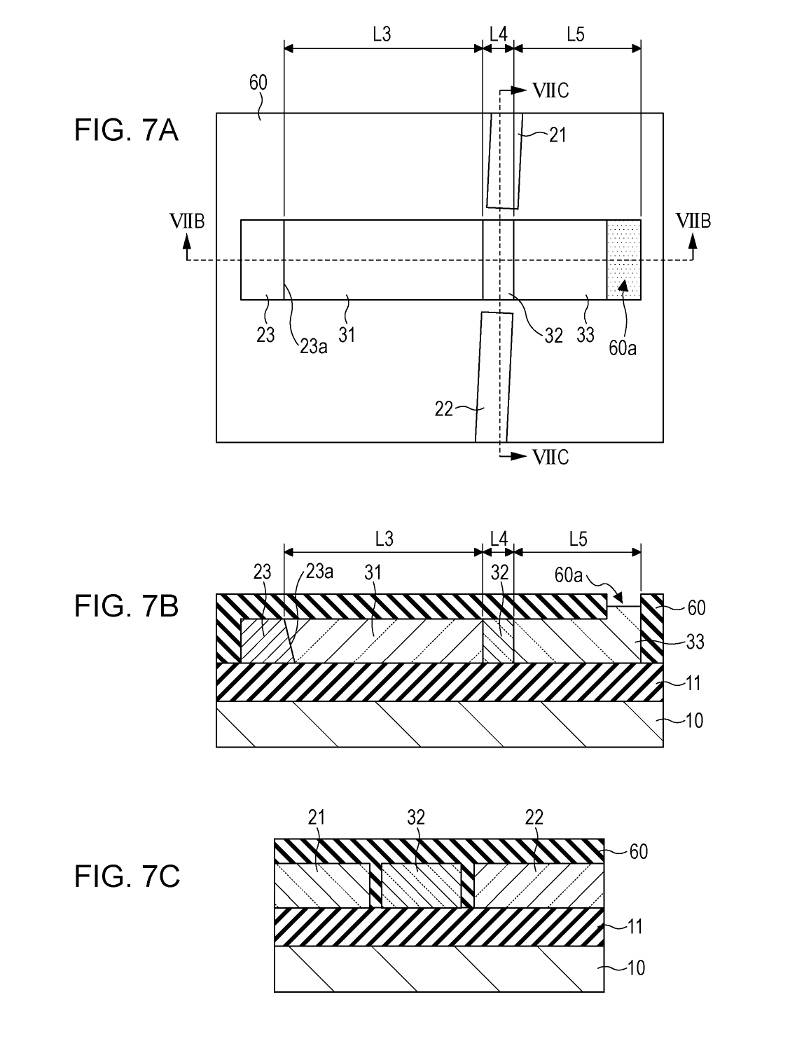

Next, as illustrated in FIGS. 7A, 7B, and 7C, the first semiconductor cladding region 31, the active region 32, and the second semiconductor cladding region 33 are sequentially formed from the (111) plane of silicon of the end surface 23a of the monocrystalline silicon region 23 by epitaxial growth by MOCVD. In epitaxial growth, crystal growth does not occur on silicon oxide with the amorphous structure, but crystal growth occurs on the (111) plane of silicon on which a crystal plane is exposed. Because crystal growth of a compound semiconductor such as InP is facilitated on the (111) plane, a film-forming gas such as organic metal enters through the opening 60a of the silicon oxide layer 60, and crystal growth starts from the (111) plane of the exposed end surface 23a of silicon. Accordingly, the first semiconductor cladding region 31 of n-InP with a length L3 of 5 μm, the active region 32 of InGaAsP with a length L4 of 500 nm, and the second semiconductor cladding region 33 of p-InP with a length L5 of 4.5 μm are formed in this order from the end surface 23a of the monocrystalline silicon region 23. When the first semiconductor cladding region 31, the active region 32, and the second semiconductor cladding region 33 are formed, crystal growth is performed while an initial substrate temperature in starting crystal growth of the first semiconductor cladding region 31 is set to approximately 450° C. and the substrate temperature is thereafter raised to approximately 550° C. FIG. 7A is a top diagram in this process, FIG. 7B is a cross-sectional diagram taken along dashed line VIIB-VIIB in FIG. 7A, and FIG. 7C is a cross-sectional diagram taken along dashed line VIIC-VIIC in FIG. 7A.

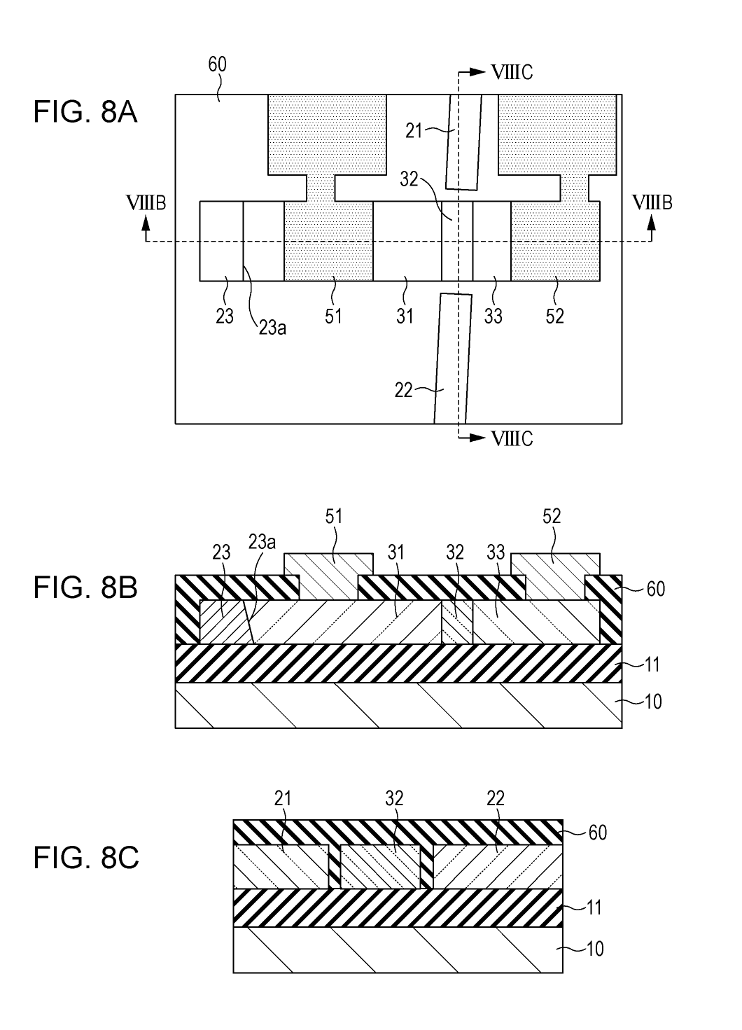

Next, as illustrated in FIGS. 8A, 8B, and 8C, the first electrode 51 to be connected with the first semiconductor cladding region 31 is formed on the first semiconductor cladding region 31, and the second electrode 52 to be connected with the second semiconductor cladding region 33 is formed on the second semiconductor cladding region 33. FIG. 8A is a top diagram in this process, FIG. 8B is a cross-sectional diagram taken along dashed line VIIIB-VIIIB in FIG. 8A, and FIG. 8C is a cross-sectional diagram taken along dashed line VIIIC-VIIIC in FIG. 8A.

For example, the silicon oxide layer 60 is coated with a photoresist, and exposure by an exposure apparatus and development are performed. Accordingly, a resist pattern is formed which has openings in a region on the first semiconductor cladding region 31 in which the first electrode 51 is formed and in a region on the second semiconductor cladding region 33 in which the second electrode 52 is formed and which is not illustrated. Subsequently, the silicon oxide layer 60 in a region in which the resist pattern is not formed is removed by dry etching such as RIE until surfaces of the first semiconductor cladding region 31 and the second semiconductor cladding region 33 are exposed. Subsequently, the resist pattern is removed by an organic solvent or the like. Subsequently, a metal laminated film is formed by sputtering, the metal laminated film is coated with a photoresist, and exposure by an exposure apparatus and development are performed. A resist pattern, which is not illustrated, is thereby formed in the regions in which the first electrode 51 and the second electrode 52 are formed. Subsequently, the metal laminated film in a region in which the resist pattern is not formed is removed by dry etching such as RIE, and the first electrode 51 to be connected with the first semiconductor cladding region 31 and the second electrode 52 to be connected with the second semiconductor cladding region 33 are thereby formed. Subsequently, the resist pattern is removed by an organic solvent or the like. The metal laminated film is formed of Ti/TiN/Al.

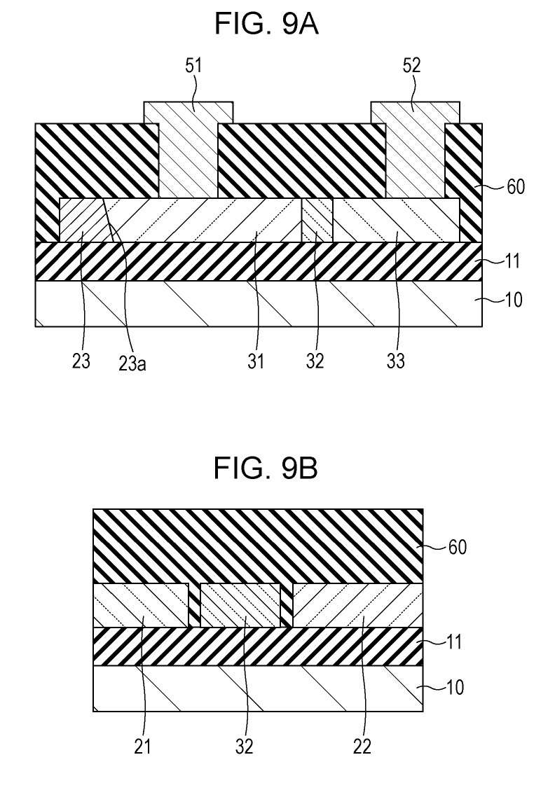

The optical device in this embodiment may be manufactured by the above process. In this embodiment, as illustrated in FIGS. 9A and 9B, film formation of a silicon oxide layer may further be performed by CVD after forming the second semiconductor cladding region 33, and the thickness of the silicon oxide layer 60 may thereby be thickened to approximately 1 μm. Subsequently, the openings are formed in the silicon oxide layer 60, and the first electrode 51 and the second electrode 52 are formed. FIGS. 9A and 9B are cross-sectional diagrams of cross sections that correspond to FIGS. 8B and 8C.

### Second Embodiment

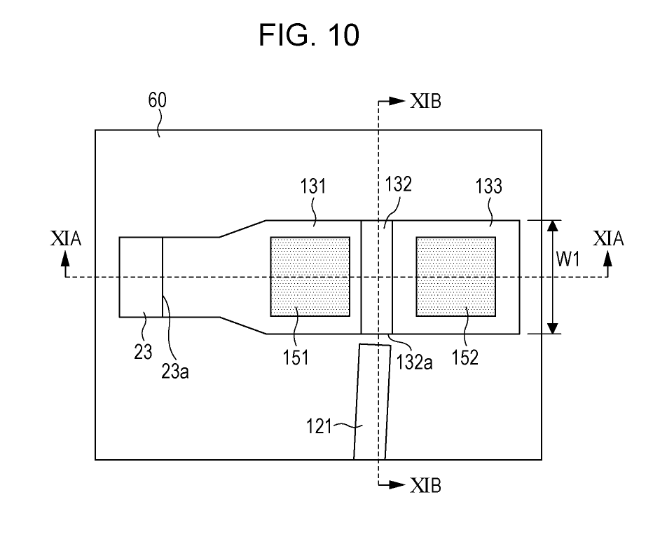

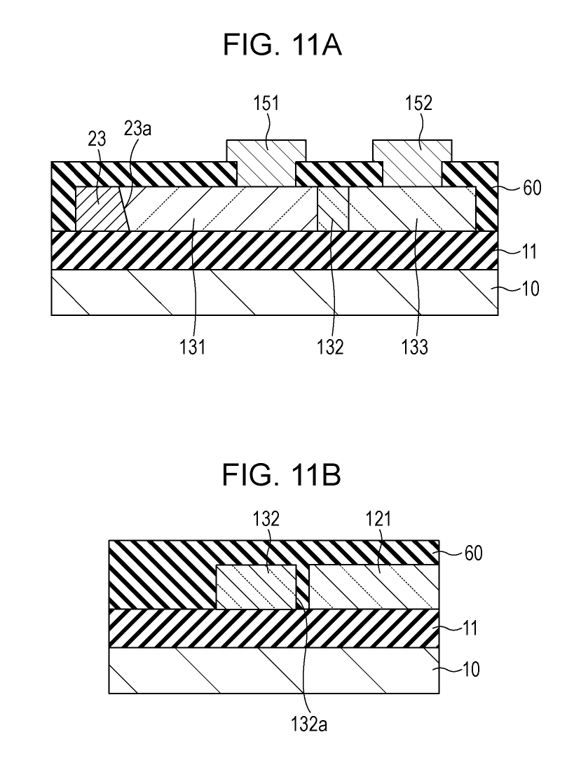

Next, a second embodiment will be described based on FIG. 10 and FIGS. 11A and 11B. In an optical device in this embodiment, an optical waveguide and a semiconductor laser are formed, and the optical device is formed on the silicon oxide layer 11 formed on the silicon substrate 10. FIG. 10 is a top diagram of the optical device in this embodiment, FIG. 11A is a cross-sectional diagram taken along dashed line XIA-XIA in FIG. 10, and FIG. 11B is a cross-sectional diagram taken along dashed line XIB-XIB in FIG. 10.

In this embodiment, an optical waveguide 121 formed of silicon and the semiconductor laser formed with a compound semiconductor are formed on the silicon oxide layer 11. The semiconductor laser is formed on the silicon oxide layer 11 along the plane direction of the silicon oxide layer 11, and a first semiconductor cladding region 131, an active region 132, and a second semiconductor cladding region 133 are formed in this order from one side to the other side. An end surface of the first semiconductor cladding region 131 as one side contacts with the (111) plane of silicon as the end surface 23a of the monocrystalline silicon region 23 formed of monocrystalline silicon.

On the monocrystalline silicon region 23, the first semiconductor cladding region 131, the active region 132, and the second semiconductor cladding region 133 that are formed on the silicon oxide layer 11, the silicon oxide layer 60 is formed to cover those. On the first semiconductor cladding region 131, a first electrode 151 is formed to contact with the first semiconductor cladding region 131. On the second semiconductor cladding region 133, a second electrode 152 is formed to contact with the second semiconductor cladding region 133. The optical device in this embodiment is formed such that laser light that is emitted from one end surface 132a of the active region 132 in the semiconductor laser is incident on the optical waveguide 121.

The silicon oxide layer 11 and the silicon oxide layer 60 are formed of silicon oxide with an amorphous structure. The first semiconductor cladding region 131 is formed of n-InP, the active region 132 is formed of InGaAsP, and the second semiconductor cladding region 133 is formed of p-InP. The active region 132 may be formed of InAs.

The first semiconductor cladding region 131 and the second semiconductor cladding region 133 are doped with impurity elements and thus have conductivity. Thus, a voltage is applied between the first electrode 151 and the second electrode 152, a current may thereby be caused to flow through the active region 132 via the first semiconductor cladding region 131 and the second semiconductor cladding region 133, and laser oscillation may be caused in the active region 132. In the active region 132, a resonator is formed in the direction in which light is propagated. The resonator may be formed with end surface mirrors that are formed over end surfaces on both sides of the active region 132. In order to form the resonator with the active region 132, a width W1 of the active region 132 is preferably 10 μm or more.

In a parallel direction with the substrate surface of the silicon substrate 10, both sides of the active region 132 are interposed between the first semiconductor cladding region 131 and the second semiconductor cladding region 133 that are formed of a semiconductor material with a lower refractive index than the active region 132. In a film-thickness direction, the active region 132 is interposed between the silicon oxide layer 11 and the silicon oxide layer 60 that are formed of silicon oxide with a lower refractive index than the active region 132. For example, the active region 132 is interposed between the first semiconductor cladding region 131 and the second semiconductor cladding region 133 in the parallel direction with the plane of the silicon substrate 10 and is interposed between the silicon oxide layer 11 and the silicon oxide layer 60 in the vertical direction to the plane of the silicon substrate 10. Thus, the light emitted in the active region 132 is trapped in the active region 132, and laser oscillation occurs.

In this embodiment, the width is narrowly formed in the vicinity of the (111) plane of the monocrystalline silicon region 23 of the first semiconductor cladding region 131, in which crystal growth of a compound semiconductor material starts, and the width becomes wider toward a region in which the active region 132 is formed. This is because the narrower width leads to the smoother crystal growth of a III-V compound semiconductor in an initial stage of crystal growth of the compound semiconductor.

The optical device in this embodiment may be formed by a similar process to the first embodiment. For example, the first optical waveguide 21 is formed without forming the second optical waveguide 22 in the first embodiment, and the optical device in this embodiment may thereby be fabricated. The drawings for this embodiment do not illustrate the opening of the silicon oxide layer 60 through which an organic metal gas enters when the first semiconductor cladding region 131, the active region 132, and the second semiconductor cladding region 133 are formed by epitaxial growth.

In this embodiment, the laser light that goes through laser oscillation in the active region 132 and is emitted from one end surface 132a of the active region 132 is incident on the optical waveguide 121. The optical device in this embodiment may use an optical detection element that detects the light which is incident on the active region from the optical waveguide instead of the semiconductor laser.

### Modification Example 1

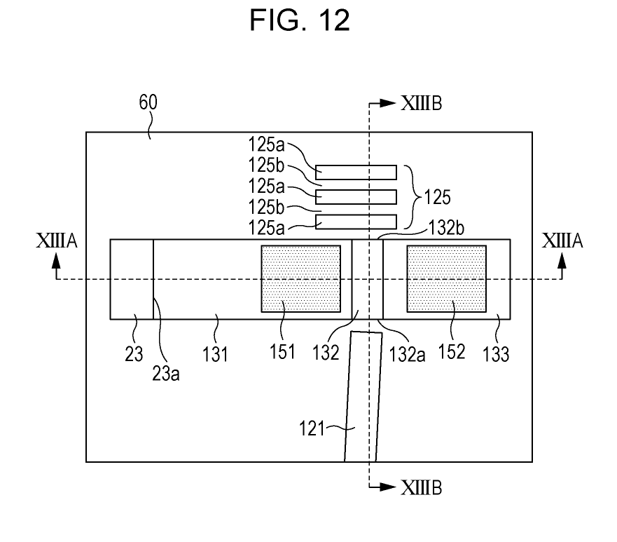

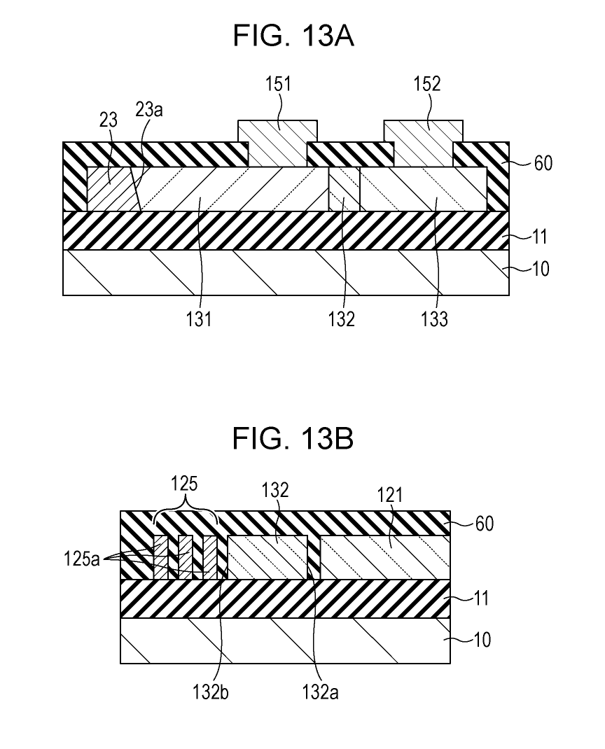

In this embodiment, as illustrated in FIG. 12 and FIGS. 13A and 13B, the optical waveguide 121 may be formed on the side of one end surface 132a in the direction in which light is propagated in the active region 132, and a mirror 125 that reflects light may be formed on the side of the other end surface 132b. The mirror 125 is formed with a distributed Bragg reflector (DBR) mirror in which silicon regions 125a and silicon oxide regions 125b are alternately formed. The silicon region 125a that forms the mirror 125 is formed by processing a silicon layer of an SOI substrate. The silicon oxide region 125b is formed of silicon oxide that is embedded between the silicon region 125a and the silicon region 125a by film formation of the silicon oxide layer 60. FIG. 12 is a top diagram of the optical device, FIG. 13A is a cross-sectional diagram taken along dashed line XIIIA-XIIIA in FIG. 12, and FIG. 13B is a cross-sectional diagram taken along dashed line XIIIB-XIIIB in FIG. 12.

### Modification Example 2

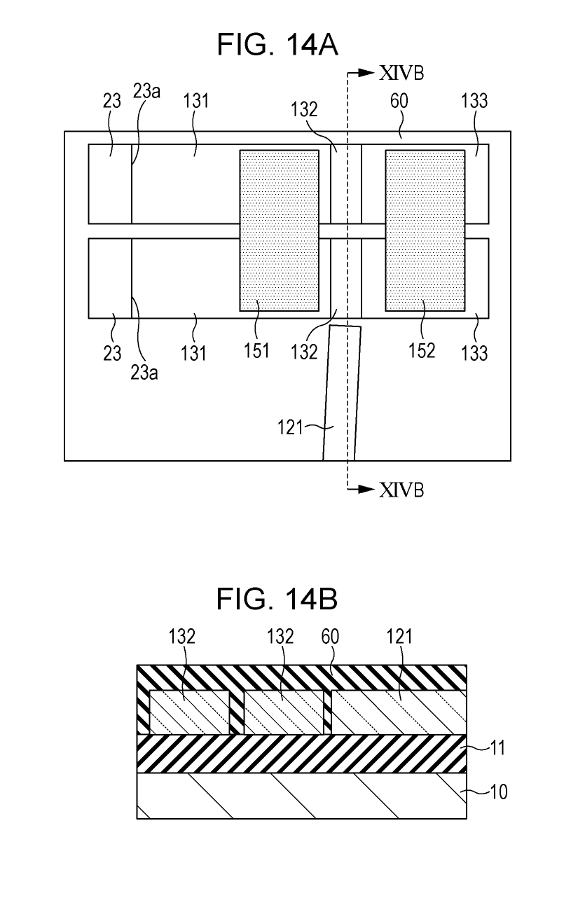

As illustrated in FIGS. 14A and 14B, this embodiment may have a structure that has two active regions 132. Accordingly, the intensity of laser light emitted from the semiconductor laser may be enhanced. FIG. 14A is a top diagram of the optical device, and FIG. 14B is a cross-sectional diagram taken along dashed line XIVB-XIVB in FIG. 14A.

For example, on the silicon oxide layer 11, two sets are side by side formed, in each of which the first semiconductor cladding region 131, the active region 132, and the second semiconductor cladding region 133 are sequentially formed from one side to the other side. The two formed active regions 132 are formed such that the direction in which light of one active region 132 is propagated and the direction in which light of the other active region 132 is propagated become the same direction. The above formation may enhance the intensity of emitted laser light.

### Modification Example 3

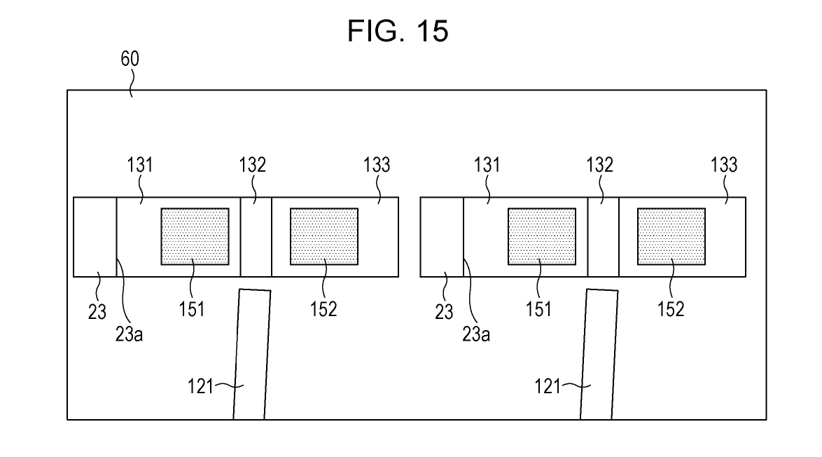

In this embodiment, as illustrated in FIG. 15, plural semiconductor lasers, which are illustrated in FIG. 10 and so forth, may be formed on the same silicon substrate.

The second embodiment and the modification examples are similar to the first embodiment except the above contents.

In the foregoing, the embodiments have been described in detail. However, the techniques described herein are not limited to specific embodiments, but various modifications and alterations are possible within the scope of the claims.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. An optical device comprising:
a lower cladding layer formed of an amorphous insulator on a substrate;
a first cladding region, an active region, and a second cladding region formed on the lower cladding layer, one of the first cladding region and the second cladding region being formed on a monocrystal;
an upper cladding layer formed of an insulator on the active region;
a first electrode connected with the first cladding region; and
a second electrode connected with the second cladding region.

2. The optical device of claim 1, wherein the lower cladding layer and the upper cladding layer are formed of a material that includes silicon oxide.

3. The optical device of claim 1, wherein
the first cladding region is a first conductivity type, and
the second cladding region is a second conductivity type.

4. The optical device of claim 1, wherein the compound semiconductor is a III-V compound semiconductor.

5. The optical device of claim 1, wherein
the first cladding region is formed of a material that includes InP,
the active region is formed of a material that includes InAs or InGaAsP, and
the second cladding region is formed of a material that includes InP.

6. The optical device of claim 1, wherein
a first optical waveguide and a second optical waveguide are formed of silicon on the lower cladding layer, and
light that is incident on the active region from the first optical waveguide is amplified and emitted in the active region and is incident on the second optical waveguide.

7. The optical device of claim 6, wherein the first optical waveguide, the second optical waveguide, the first cladding region, the active region, and the second cladding region are formed in parallel with a plane of the substrate.

8. The optical device of claim 1, wherein
an optical waveguide is formed of silicon on the lower cladding layer,
the optical waveguide, the first cladding region, the active region, and the second cladding region are formed in parallel with a plane of the substrate, and
laser light emitted in the active region is incident on the optical waveguide.

9. The optical device of claim 8, wherein
a mirror is formed over the substrate, and
the active region is formed between the optical waveguide and the mirror.

10. The optical device of claim 9, wherein the mirror is a distributed Bragg reflector in which silicon regions and silicon oxide regions are alternately formed.

11. The optical device of claim 1, wherein an optical waveguide is formed of silicon on the lower cladding layer,
the optical waveguide, the first cladding region, the active region, and the second cladding region are formed in parallel with a plane of the substrate, and
light that is incident on the active region from the optical waveguide is detected.

12. The optical device of claim 1, wherein first cladding regions, active regions, and second cladding regions formed on the lower cladding layer.

13. A method for manufacturing an optical device, the method comprising:
forming a monocrystalline silicon layer with monocrystalline silicon on an amorphous lower silicon oxide layer on a substrate;
forming an upper silicon oxide layer that covers the monocrystalline silicon layer;
forming an opening by removing a portion of the upper silicon oxide layer on the monocrystalline silicon layer;
forming a monocrystalline silicon region by removing a portion of the monocrystalline silicon layer by wet etching through the opening to expose a (111) plane of silicon of the monocrystalline silicon region;
forming a first cladding region, an active region, and a second cladding region sequentially by epitaxial growth of a compound semiconductor from the (111) plane of silicon; and
forming a first electrode that contacts with the first cladding region and a second electrode that contacts with the second cladding region.

14. The method for manufacturing an optical device of claim 13, wherein
in the forming of the monocrystalline silicon layer, a first optical waveguide and a second optical waveguide are simultaneously formed of monocrystalline silicon on the lower silicon oxide layer,
the upper silicon oxide layer is formed on the first optical waveguide and the second optical waveguide, and
the active region is formed to be positioned between the first optical waveguide and the second optical waveguide.

15. The method for manufacturing an optical device of claim 13, wherein
in the forming of the monocrystalline silicon layer, an optical waveguide is simultaneously formed of monocrystalline silicon on the lower silicon oxide layer,
the upper silicon oxide layer is formed on the optical waveguide, and
the optical waveguide is formed in a position on which light emitted from the active region is incident.

16. The method for manufacturing an optical device of claim 13, wherein the wet etching of silicon is performed by using an etching solution whose etching rate for silicon is higher than an etching rate for silicon oxide.

17. The method for manufacturing an optical device of claim 13, wherein the first cladding region, the active region, and the second cladding region are formed by MOCVD.

18. The method for manufacturing an optical device of claim 17, wherein the first cladding region, the active region, and the second cladding region are formed by epitaxial growth in parallel with a plane of the substrate.

19. The method for manufacturing an optical device of claim 13, wherein the compound semiconductor is a III-V compound semiconductor.

20. The method for manufacturing an optical device of claim 13, wherein
the first cladding region is formed of a material that includes InP,
the active region is formed of a material that includes InAs or InGaAsP, and
the second cladding region is formed of a material that includes InP.
